(19) United States
(12) Patent Application Publication
(10) Pub. No.: US 2007/0254420 A1
(43) Pub. Date: Nov. 1, 2007

(54) SOURCE/DRAIN IMPLANTATION AND CHANNEL STRAIN TRANSFER USING DIFFERENT SIZED SPACERS AND RELATED SEMICONDUCTOR DEVICE

(75) Inventors: Atul C. Ajmera, Wappingers Falls, NY (US); Christopher V. Baiocco, Newburgh, NY (US); Xiangdong Chen, Poughquag, NY (US); Thomas W. Dyer, Pleasant Valley, NY (US); Sunfei Fang, LaGrangeville, NY (US); Wenzhi Gao, Beacon, NY (US)

Correspondence Address: HOFFMAN, WARNICK & D'ALESSANDRO LLC, 75 STATE ST, 14TH FL, ALBANY, NY, 12207, US

(73) Assignees: International Business Machines Corporation, Armonk, NY (US); Chartered Semiconductor Manufacturing LTD., Street Two (SG)

(21) Appl. No.: 11/380,743

(22) Filed: Apr. 28, 2006

(51) Int. Cl. H01L 21/338; H01L 21/20; H01L 29/76

(52) U.S. Cl. 438/179; 257/E21.437; 257/E21.438; 438/683; 257/408; 438/384

(57) ABSTRACT

Methods for source/drain implantation and strain transfer to a channel of a semiconductor device and a related semiconductor device are disclosed. In one embodiment, the method includes using a first size spacer for deep source/drain implantation adjacent a gate region of a semiconductor device; and using a second, smaller size spacer for silicide formation adjacent the gate region and transferring strain from a stress liner to a channel underlying the gate region. One embodiment of a semiconductor device may include a gate region atop a substrate; a spacer including a spacer core and an outer spacer member about the spacer core; a deep source/drain region within the substrate and distanced from the spacer; and a silicide region within the substrate and overlapping and extending beyond the deep source/drain region, the silicide region aligned to the spacer.

### BACKGROUND OF THE INVENTION

1. Technical Field

The invention relates generally to semiconductor device fabrication, and more particularly, to methods for source/drain implantation and strain transfer into a channel using different sized spacers, and a related semiconductor device.

2. Background Art

Silicon nitride (Si₃N₄) stress inducing liners have been used to improve semiconductor device performance by providing enhanced carrier mobility in a channel underlying a gate region. As shown in FIG. 1, the strain induced in a channel 10 by a stress inducing liner 12 is sensitive to a distance D1 between stress inducing liner 12 and an adjacent gate region 14, which is defined by the thickness of a spacer 16 about gate region 14. The strain in channel 10 also depends on the volume of stress liner 12. As complementary metal-oxide semiconductor field effect transistor (CMOS FET) technology continues to scale downward, the minimum poly conductor (PC) pitch is also scaling down, e.g., about 190 nm. Unfortunately, spacer 16 thickness has not been scaled down to control the short channel effect. As a result, little strain can be transferred into channel 10 for a minimum pitch device.

US Patent Application Publication No. US2005260808A1 to Chen et al. discloses a method of forming a gate structure that includes forming disposable spacers abutting a gate region, forming source/drain regions, forming a silicide region atop the source/drain regions, removing the disposable spacers and then depositing a stress inducing liner atop the gate region to provide a stress to a portion of the gate region. This approach, however, may cause silicide damage and increase silicide resistance.

There is a need in the art for a solution to the problem(s) of the related art.

### SUMMARY OF THE INVENTION

Methods for source/drain implantation and strain transfer to a channel of a semiconductor device and a related semiconductor device are disclosed. In one embodiment, the method includes using a first size spacer for deep source/drain implantation adjacent a gate region of a semiconductor device; and using a second, smaller size spacer for silicide formation adjacent the gate region and transferring strain from a stress liner to a channel underlying the gate region. One embodiment of a semiconductor device may include a gate region atop a substrate; a spacer including a spacer core and an outer spacer member about the spacer core; a deep source/drain region within the substrate and distanced from the spacer; and a silicide region within the substrate and overlapping and extending beyond the deep source/drain region, the silicide region aligned to the spacer.

A first aspect of the invention provides a method comprising the steps of: using a first size spacer for deep source/drain implantation adjacent a gate region of a semiconductor device; and using a second, smaller size spacer for silicide formation adjacent the gate region and transferring strain from a stress liner to a channel underlying the gate region.

A second aspect of the invention provides a method comprising the steps of: forming a gate region atop a substrate; forming a spacer core about the gate region; forming a first outer spacer member about the spacer core, the first outer spacer member having a first thickness; forming deep source/drain regions in the substrate; removing at least a portion of the first outer spacer member; forming a second outer spacer member about the spacer core, the second outer spacer member having a second thickness less than the first thickness so as to expose a surface portion of the substrate between the deep source/drain regions and the gate region; forming a silicide region overlapping and extending beyond the deep source/drain regions, the silicide region aligned to the second outer spacer member; and forming a stress inducing liner over at least the exposed surface portion, wherein the stress inducing liner provides a stress to a portion of the substrate underlying the gate region.

A third aspect of the invention provides a semiconductor device comprising: a gate region atop a substrate; a spacer including a spacer core and an outer spacer member about the spacer core; a deep source/drain region within the substrate and distanced from the spacer; and a silicide region within the substrate and overlapping and extending beyond the deep source/drain region, the silicide region aligned to the spacer.

The illustrative aspects of the present invention are designed to solve the problems herein described and/or other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a conventional semiconductor device having a stress inducing liner thereover.

FIG. 2 shows a semiconductor device according to one embodiment of the invention at a stage of processing in which a stress inducing liner is provided thereover.

FIGS. 3-8 show one embodiment of a method according to the invention.

It is noted that the drawings of the invention are not to scale. The drawings are intended to depict only typical aspects of the invention, and therefore should not be considered as limiting the scope of the invention. In the drawings, like numbering represents like elements between the drawings. However, like shading does not necessarily indicate identical materials.

### DETAILED DESCRIPTION

As indicated above, the invention provides methods for source/drain implantation and strain transfer to a channel of a semiconductor device and a related semiconductor device.

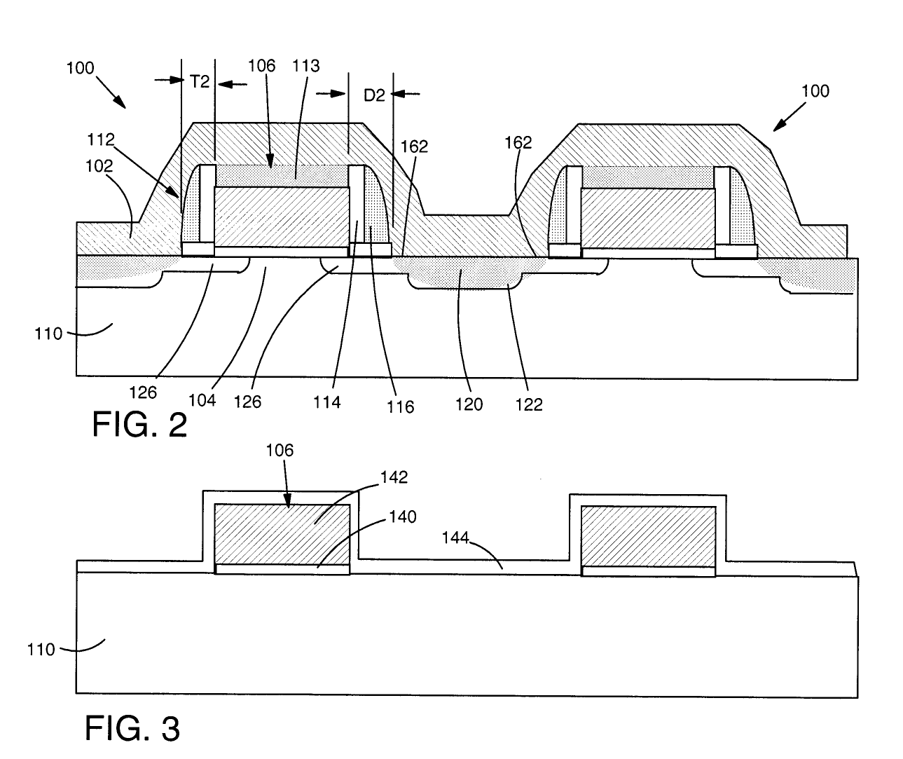

Turning to FIG. 2, a semiconductor device 100 according to one embodiment of the invention at a stage of processing in which a stress inducing liner 102 is provided thereover is illustrated. (Note, two semiconductor devices 100 that are substantially identical are shown in FIGS. 2-8; however, only one is labeled with all references for clarity). As known in the art, stress inducing liner 102 may include silicon nitride (Si₃N₄) having a stress therein, e.g., compressive or tensile depending on device type, for transferring of strain into a channel 104 under a gate region 106. In one embodiment, semiconductor device 100 includes gate region 106 atop a substrate 110 and a spacer 112 about gate region 106. A silicide region 113 may be provided atop gate region 106. Spacer 112 includes a spacer core 114 and an outer spacer member 116 about spacer core 112, i.e., a dual spacer. Spacer 112 may include any now known or later developed spacer material. For example, in one embodiment, spacer core 114 includes silicon dioxide (SiO₂) and outer spacer member 116 includes silicon nitride (Si₃N₄). In one embodiment, spacer 112 has a thickness of no less than 2 nm and no greater than 20 nm. In addition, semiconductor device 100 includes a silicide region 120 adjacent to gate region 106 in substrate 110 and a deep source/drain region 122 within silicide region 120. Silicide region 120 is aligned to spacer 112, i.e., an outer edge of spacer 112, but deep source/drain region 122 is distanced from spacer 112. Source/drain extensions 126 that are shallower than deep source/drain region 122 may also be provided. A portion of substrate 110 underlying gate region 106, i.e., channel 104, includes a stress therein that is transferred from stress inducing liner 102, which is removed from semiconductor device 100 subsequent to the stage of processing shown in FIG. 2.

Turning to FIGS. 3-8, embodiments of methods of forming semiconductor device 100 are illustrated. In a first step, shown in FIG. 3, gate region 106 is formed atop substrate 110 in any now known or later developed fashion. For example, a gate dielectric material 140, e.g., silicon dioxide (SiO₂) may be deposited and patterned followed by deposition of a gate conductor material 142 such as polysilicon, which may be deposited and patterned into gate region 106. A next step may include forming spacer core 114 (FIG. 2) about gate region 106. FIG. 3 shows a first part of this step including depositing a spacer core material layer 144. As noted above, spacer core 114 may include, for example, silicon dioxide (SiO₂) or other dielectric material, the former of which may be formed by oxidation or low temperature oxidation (LTO), or any other insulator such as aluminum oxide.

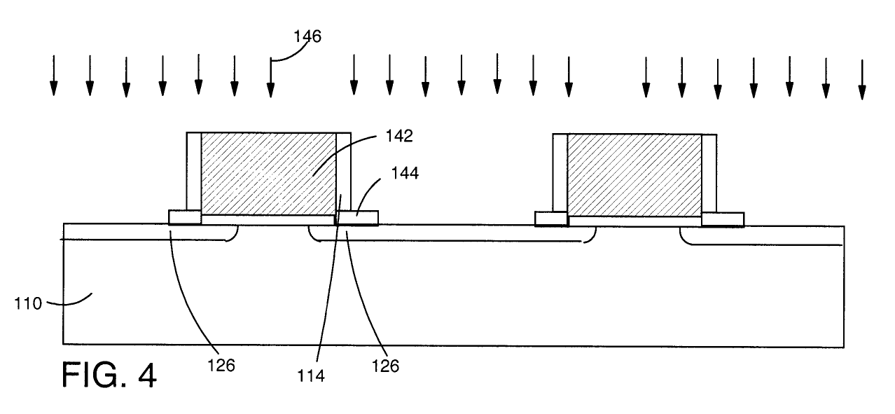

Next, as shown in FIG. 4, spacer core material 144 is etched to form spacer core 114, e.g., by a reactive ion etch. In an alternative embodiment, source/drain extensions 126 and halos (not shown) may be implanted 146 after spacer core 114 formation. Implant 146 may include any now known or later developed implantation for forming source/drain extensions 126, e.g., arsenic for NFET and boron di-fluoride (BF₂) for PFET.

FIG. 5 shows a next step including forming a first outer spacer member 150 about spacer core 114. First outer spacer member 150 may include silicon nitride (Si₃N₄). First outer spacer member 150 may be formed in any now known or later developed fashion such as by deposition of silicon nitride (Si₃N₄), and etching. As will be described in greater detail, first outer spacer member 150 has a thickness which is greater than a thickness of outer spacer member 116, as shown in FIG. 2. For example, spacer core 114 and first outer spacer member 150 may have a thickness T1 (FIG. 5) of 15-50 nm, while spacer core 114 and outer spacer member 116 (FIG. 2) may have a thickness T2 of 2-20 nm. FIG. 5 also shows a next step of forming deep source/drain regions 154 in substrate 110, e.g., by implanting 156 a dopant into substrate 110. In one embodiment, implant 156 includes a deep source/drain implantation, e.g., to a depth of about 700-1500 Å deep, and anneal.

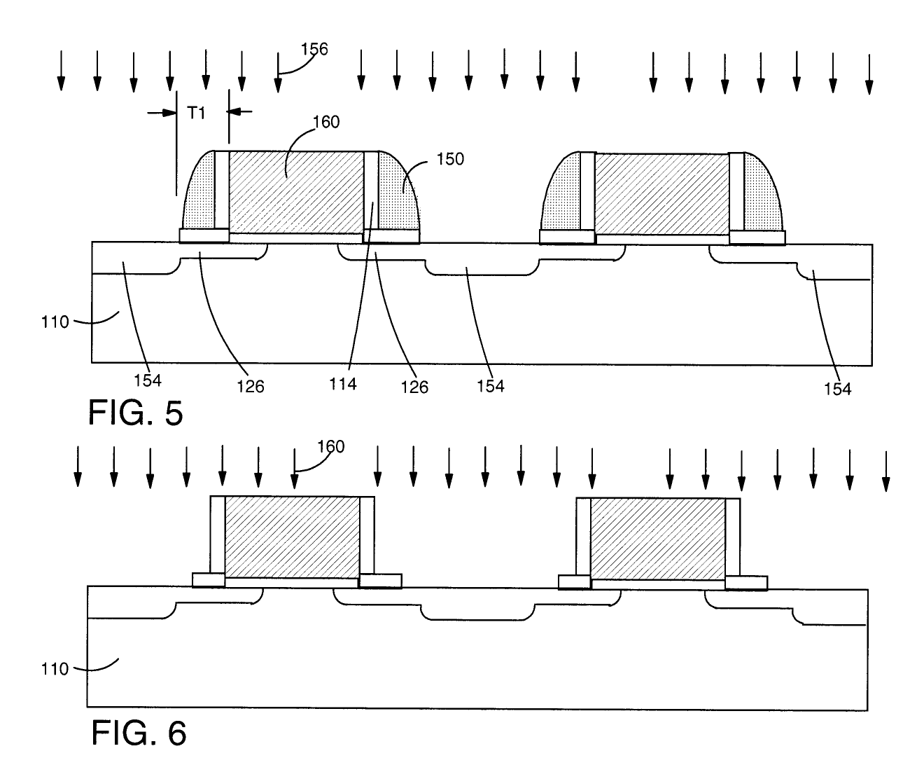

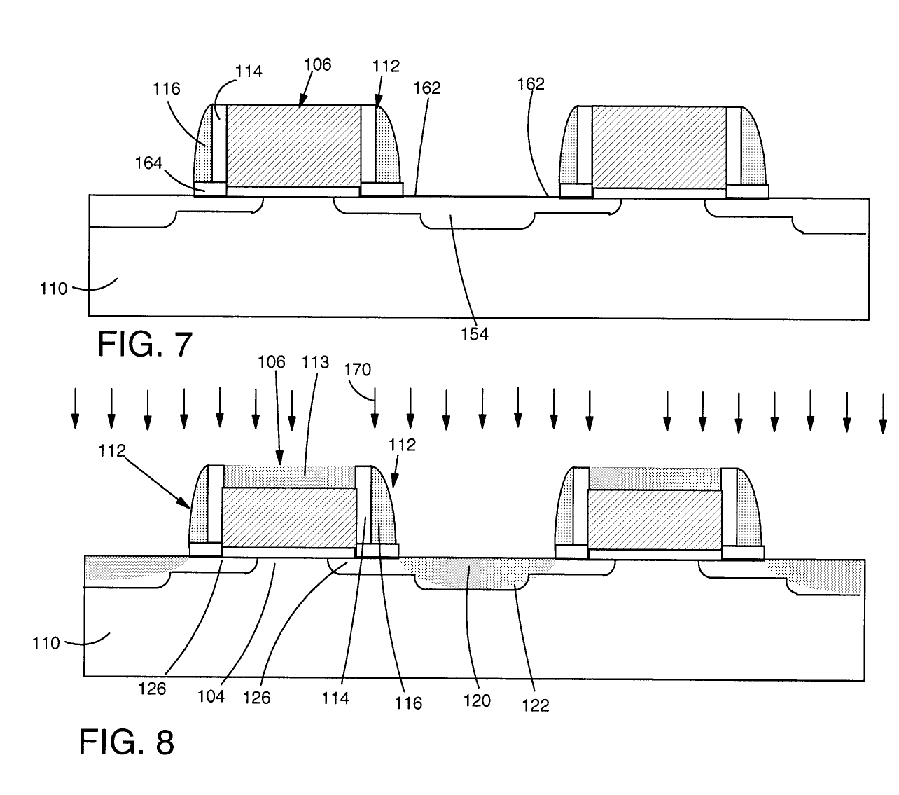

Next, as shown in FIG. 6, at least a portion of first outer spacer member 150 (FIG. 5) is removed, e.g., by a reactive ion etch (RIE) or a wet etch 160. FIG. 7 shows a next step of forming second outer spacer member 116 about spacer core 114 to form spacer 112 (FIGS. 2 and 7). As noted above, second outer spacer member 116 may include silicon nitride (Si₃N₄). This step may include depositing silicon nitride (Si₃N₄) layer and etching to form outer spacer member 116. A lower portion 164 of spacer core 114 may be trimmed, as necessary, to accommodate the smaller, second outer spacer member 116. Because second outer spacer member 116 has thickness less than a thickness of first outer spacer member 150 (FIG. 5), a surface portion 162 of substrate 110 is exposed by spacer 112 between source/drain regions 154 and gate region 106.

FIG. 8 shows a next step of forming silicide region 120 overlapping and extending beyond deep source/drain region 122. Silicide region 120 is aligned to outer spacer member 116 of spacer 112, but deep source/drain region 122 is spaced from spacer 112.

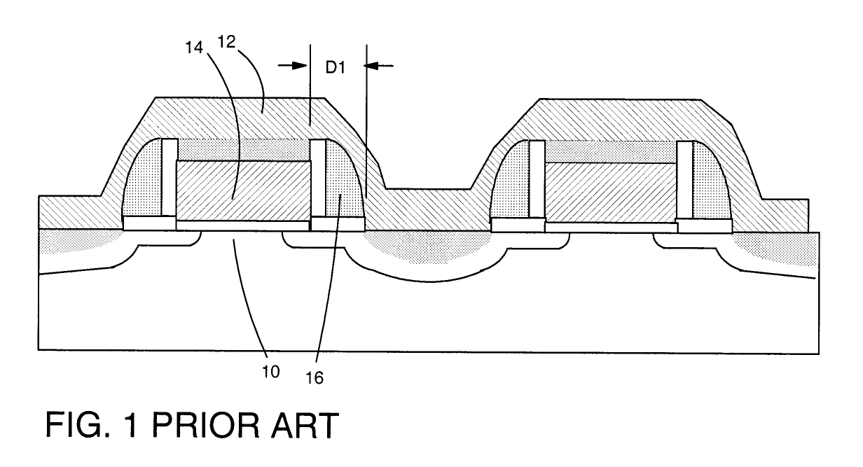

Returning to FIG. 2, a next step include forming stress inducing liner 102 over at least exposed surface portion 162. As described above, stress inducing liner 102 provides a stress to a portion of substrate 110, i.e., channel 104, underlying gate region 106, which improves performance of semiconductor device 100. Thinner spacer 112 is used to define distance D2 (FIG. 2) between stress inducing liner 102 and channel 104 that is less than distance D1 (FIG. 1) in a conventional semiconductor device 10 (FIG. 1). As a result, stress inducing liner 102 is moved closer to gate region 106, which provides more space and volume for stress inducing liner 102 and better strain transfer to channel 104. In addition, the doping profile for deep source/drain regions 122 can be kept the same as with a conventional spacer process, but the short channel effect is not degraded. Non-removal of spacer 112 after silicide region 120 formation (FIG. 8) also avoids damaging silicide region 120, e.g., prevents silicide pipe to deep source/drain regions 122, and complicating the process.

In an alternative embodiment, a method may include using a first size spacer 114, 150 (FIG. 5) for source/drain implantation 156 (FIG. 5) adjacent gate region 106 of semiconductor device 100, and using a second, smaller size spacer 112 (114, 116) for silicide formation 170 (FIG. 8) adjacent gate region 106 and transferring strain from stress liner 102 (FIG. 2) to channel 104 underlying gate region 106. As noted above, each spacer includes spacer core 114 and an outer spacer member 150 or 116. Using second, smaller size spacer 112 (114, 116) includes removing at least a portion of outer spacer member 150 of the larger size spacer 114, 150 after source/drain implantation 156 (FIG. 5), and forming outer spacer member 116 that is smaller than the removed outer spacer member 150 to form smaller size spacer 112 (114, 116).

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

1. A method comprising the steps of:
first, using a first size spacer for deep source/drain implantation adjacent a gate region of a semiconductor device;
second, using a second, smaller size spacer for silicide formation adjacent the gate region, wherein each spacer includes a spacer core and an outer spacer member, and wherein the second, smaller size spacer using step includes:
removing at least a portion of the outer spacer member of the first size spacer after the deep source/drain implantation; and
replacing the removed portion of the outer spacer member with a second outer spacer member that is smaller than the removed portion of the outer spacer member to form the second, smaller size spacer; and
finally, forming a stress inducing liner over at least an exposed surface portion of a substrate between the deep source/drain implantation and the gate region for transferring strain from the stress inducing liner to a channel underlying the gate region.

2. (canceled)

3. The method of claim 1, wherein the spacer core includes silicon dioxide (SiO₂) and the outer spacer member includes silicon nitride (Si₃N₄).

4. (canceled)

5. The method of claim 1, wherein the removing step includes performing one of a reactive ion etch and a wet etch.

6. The method of claim 1, wherein the second, smaller size spacer using step includes:
removing at least a portion of the first size spacer after the deep source/drain implantation; and
forming the second, smaller size spacer.

7. The method of claim 6, wherein the removing step includes performing one of a reactive ion etch and a wet etch.

8. The method of claim 1, wherein the first size spacer has a thickness of no less than 15 nm and no greater than 50 nm, and the second, smaller size spacer has a thickness of no less than 2 nm and no greater than 20 nm.

9. A method comprising the steps of:
forming a gate region atop a substrate;
forming a spacer core about the gate region;
forming a first outer spacer member about the spacer core, the first outer spacer member having a first thickness;
forming deep source/drain regions in the substrate;
removing at least a portion of the first outer spacer member;
replacing the removed portion of the first outer spacer layer with a second outer spacer member about the spacer core, the second outer spacer member having a second thickness less than the removed portion of the first outer spacer member thickness so as to expose a surface portion of the substrate between the deep source/drain regions and the gate region;
forming a silicide region overlapping and extending beyond the deep source/drain regions, the silicide region aligned to the second outer spacer member; and
finally, forming a stress inducing liner over at least the exposed surface portion and the second outer spacer member, wherein the stress inducing liner provides a stress to a portion of the substrate underlying the gate region.

10. The method of claim 9, wherein the spacer core includes silicon dioxide (SiO₂) and each outer spacer member includes silicon nitride (Si₃N₄).

11. The method of claim 9, wherein the spacer core and the first outer spacer member have a thickness of no less than 15 nm and no greater than 50 nm, and the spacer core and the second outer spacer member have a thickness of no less than 2 nm and no greater than 20 nm.

12. The method of claim 9, wherein the removing step includes performing one of a reactive ion etch and a wet etch.

13. The method of claim 9, further comprising the step of implanting source/drain extensions after the spacer core forming step.

14. The method of claim 9, wherein the spacer core forming step includes depositing a silicon dioxide (SiO₂) material and etching to form the spacer core.

15. A semiconductor device comprising:
a gate region atop a substrate;
a spacer including a spacer core and an outer spacer member about the spacer core, wherein the spacer has a thickness of no less than 2 nm and no greater than 20 nm;
a deep source/drain region within the substrate and distanced from the spacer;
a stress inducing liner over at least an exposed surface portion of the substrate between the deep source/drain region and the gate region for transferring strain from the stress inducing liner to a channel underlying the gate region; and
a silicide region within the substrate and overlapping and extending beyond the deep source/drain region, the silicide region aligned to the second spacer.

16. (canceled)

17. The semiconductor device of claim 15, wherein the spacer core includes silicon dioxide (SiO₂) and the outer spacer member includes silicon nitride (Si₃N₄).

18. The semiconductor device of claim 15, further comprising a stress in a portion of the substrate underlying the gate region.

19. The semiconductor device of claim 15, further comprising source/drain extensions.

20. The semiconductor device of claim 15, further comprising a silicide region atop the gate region.
